(19) United States
(12) Patent Application Publication
(10) Pub. No.: US 2023/0110638 A1
(43) Pub. Date: Apr. 13, 2023

(54) Display Device and Method for Manufacturing the Same

(71) Applicant: LG Display Co., Ltd., Seoul (KR)

(72) Inventors: Cheolwoo Na, Paju-si (KR); Jaekun Kim, Paju-si (KR)

(21) Appl. No.: 17/960,508

(22) Filed: Oct. 5, 2022

(30) Foreign Application Priority Data
Oct. 8, 2021 (KR) 10-2021-0133740

(51) Int. Cl. H01L 51/52; H01L 51/56; H01L 51/00

(52) U.S. Cl. CPC H01L 51/524; H01L 51/56; H01L 51/0097

(57) ABSTRACT

The disclosure relates to a display device and a method for manufacturing the display device. The display device according to an embodiment of the disclosure includes a lower substrate, a display element on the lower substrate, a pad disposed on the lower substrate along a periphery of the lower substrate, and a cover glass disposed on the pad and covering the lower substrate and the pad, and the pad includes a first partial pad and a second partial pad, wherein at least a portion of the first partial pad overlaps at least a portion of the second partial pad.

### CROSS REFERENCE TO RELATED APPLICATION

The present application claims priority to Korean Patent Application No. 10-2021-0133740, filed Oct. 8, 2021, the entire contents of which is incorporated herein for all purposes by this reference.

The present disclosure relates to a waterproof and dustproof display device and a method for manufacturing the same.

### BACKGROUND OF TECHNOLOGY

A display device for televisions (TVs), monitors, smart phones, etc. has a coupled structure of an image display substrate and a cover substrate for protecting the image display substrate thereon. The image display substrate has a micro element and thus is sensitive to dust or moisture. Therefore, waterproof and dustproof capabilities of the display device may affect a lifespan of the product.

The display device may have a sealing member which is interposed between and along a periphery of the substrates and is formed in a single-piece, for providing waterproof and dustproof protection to the display device. For example, the single-piece type sealing member may be formed by removing an inside of the material having a same size as the display device, leaving only a thickness of the sealing member. In this case, there is a problem in that it is not possible to repeatedly produce a sealing member of the same size with the remaining portion of the material, resulting in a decrease in productivity.

Another problem is in that air is contained in the process of placing the sealing member on the substrate and covering with the cover substrate thereon, but the air cannot escape due to the single-piece type sealing member, thereby forming an excessive air gap in the display device.

### SUMMARY

Accordingly, the purpose of the present disclosure includes but no limited to providing a display device which is excellent in waterproofing and dustproofing and has high productivity, and a method for manufacturing the same.

In one embodiment, a display device comprises: a lower substrate; a display element on the lower substrate, the display element configured to emit light; a pad disposed on the lower substrate along a periphery of the lower substrate, the pad comprising a first partial pad and a second partial pad, wherein a portion of the first partial pad overlaps a portion of the second partial pad on the lower substrate; and a cover glass on the pad, the cover glass covering the lower substrate and the pad.

In one embodiment, a method for manufacturing a display device comprises: disposing a first partial pad on the lower substrate along a periphery of a lower substrate on which a display element is disposed; disposing a second partial pad on the lower substrate along the periphery of the lower substrate such that a portion of the first partial pad overlaps a portion of the second partial pad; disposing a cover glass on the first partial pad and the second partial pad such that the cover glass covers the lower substrate, the first partial pad, and the second partial pad; and compressing the lower substrate and the cover glass such that a gap that is between the first partial pad and the second partial pad is reduced.

In one embodiment, a display device comprises: a lower substrate; a display element on the lower substrate, the display element configured to emit light; a pad disposed on the lower substrate along a periphery of the lower substrate, the pad comprising a first partial pad and a second partial pad, wherein a portion of the first partial pad overlaps a portion of the second partial pad on the lower substrate; and a cover glass on the pad, the cover glass covering the lower substrate and the pad, wherein an innermost outer edge of the first partial pad or an innermost outer edge of the second partial pad does not respectively extend past an outermost outer edge of the first partial pad or an outermost outer edge of the second partial pad in a plan view of the display device after compression of the lower substrate, the pad, and the cover glass.

In various embodiments of the present disclosure, there is disclosed a configuration of overlappingly disposed partial pads.

Manufacturing of the pad in a combining-type has superior productivity compared to manufacturing the pad in a single-piece type. Specifically, the manufacturing method of the pad in a combining-type can mass produce a large plurality of the pads from a material and significantly reduce the amount of a material discarded wastefully. As a result, the method of manufacturing the pad in a combining-type has an effect of reducing costs involved in producing the pads and therefore the display device.

In addition, the configuration of overlappingly disposing the pads has an advantage of securing excellent waterproof and dustproof functions compared to disposing the pads merely to be in close contact. Specifically, the overlapping arrangement of the pads can solve the problem of deteriorating waterproof and dustproof capabilities by a gap between the pads and formed when disposing the pads merely to be in close contact.

Furthermore, the display device according to various embodiments of the present disclosure may reduce an air gap that occurs during a manufacturing process of the display device, compared to a single-piece type sealing member. Through the steps of overlappingly disposing the pads and compressing the cover glass and the substrate to be closer, air may escape and the display device can maintain an air gap at an appropriate level.

According to some embodiments of the present disclosure, the display device may have improved waterproof and dustproof capabilities and a better finish based on various shapes of the partial pads and overlapping ways between the partial pads.

Also, according to some embodiments of the present disclosure, the display device has superior waterproof and dustproof protection or has an effect of compensating for dimensional deformation and the like during the manufacturing process, based on the arrangement of the partial pads and the layered structure of the pad.

### BRIEF DESCRIPTION OF THE DRAWINGS

FIG. 1 is a top plan view illustrating a display device according to an embodiment of the present disclosure;

FIG. 2 is a cross-sectional view illustrating the display device according to an embodiment of the present disclosure;

FIG. 3 is a cross-sectional view illustrating an overlapping area of partial pads of the display device according to an embodiment of the present disclosure;

FIG. 4 is a cross-sectional view illustrating an air gap during a manufacturing process of the display device according to an embodiment of the present disclosure;

FIGS. 5A to 5D shows top plan views of examples of various shapes of the partial pad according to an embodiment of the present disclosure;

FIG. 6 is a cross-sectional view illustrating that the pad protruding to an outside of a substrate by an overlapping arrangement.

FIG. 7 is a top plan view illustrating a partial pad according to another embodiment of the present disclosure;

FIGS. 8A to 8D are top plan views of a pad according to various embodiments of the present disclosure;

FIG. 9 is a view illustrating a shape of the partial pad manufactured according to an embodiment of the present disclosure;

FIGS. 10A to 10B shows top plan views of protruding portions of the partial pads according to an embodiment of the present disclosure;

FIGS. 11A to 11B shows top plan views of configurations of the protruding portions according to an embodiment of the present disclosure;

FIG. 12 is a top plan view of a configuration of the protruding portions according to another embodiment of the present disclosure;

FIG. 13 is a cross-sectional view illustrating a multilayered pad according to an embodiment of the present disclosure;

FIG. 14 shows in cross-sectional views an overlapping area of the multilayered pads according to an embodiment of the present disclosure;

FIG. 15 shows properties of a stretchable substrate layer and a polyethylene terephthalate (PET) substrate layer according to an embodiment of the present disclosure;

FIGS. 16A to 16B shows reworking of the display device according to the respective substrate layers according to an embodiment of the present disclosure;

FIGS. 17 and 18 are views of the pad to which a resin is applied before compressing of the cover glass according to an embodiment of the present disclosure; and

FIG. 19 is a view of the pad to which a resin is applied after compressing of the cover glass according to an embodiment of the present disclosure.

### DETAILED DESCRIPTION

The descriptions irrelevant to the present disclosure will be omitted for clarity and conciseness, and the same reference numbers will be used throughout the description and the drawings to refer to the same or like components.

Hereinafter, embodiments of the present disclosure will be described in more detail with reference to the accompanying drawings, and therefore the technical ideas of the present disclosure can be easily practiced by a person skilled in the art. However, the present disclosure should be construed as including various modifications and changes and is not limited to the following embodiments.

It should also be noted that, when an embodiment may be implemented differently, specific processing may occur out of the order noted in the description. For example, two process steps in succession may be executed substantially concurrently or in the reverse order with respect to the described order.

In the drawings, each component may be exaggerated or reduced in size for clarity of illustration. For example, the size and thickness of each component in the drawings are arbitrarily denoted for the sake of convenience in explanation, and the present disclosure is not necessarily limited thereto.

In the following, there is disclosed a display device having a pad for waterproof and dustproof purposes between a lower substrate on which a display element is disposed and a cover glass covering the lower substrate. More specifically, there is disclosed a display device including partial pads and having an overlapping structure of the partial pads.

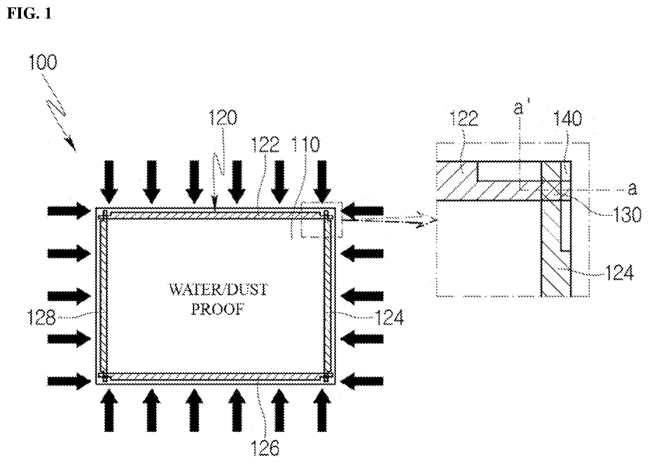

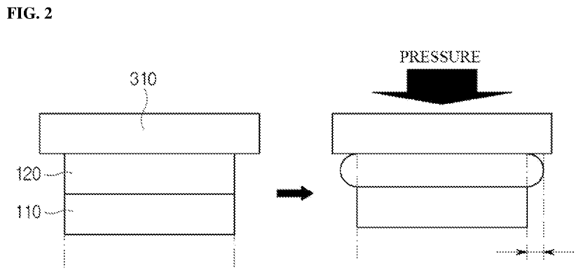

FIG. 1 is a top plan view illustrating a display device according to an embodiment of the present disclosure, and FIG. 2 is a cross-sectional view illustrating the display device according to an embodiment of the present disclosure. In FIG. 1, it is appreciated that a cover glass is transparent and therefore is not illustrated. The configuration of the cover glass can be clearly recognized in the cross-sectional view of FIG. 2.

Referring to FIG. 1, a display device 100 according to an embodiment of the present disclosure includes a lower substrate 110 on which a display element is disposed, a pad 120 (e.g., a sealing member) disposed on and along a periphery of the lower substrate 110, and a cover glass 310 disposed on the pad 120 and covering the lower substrate 110. Further, the pad 120 may be configured to include a first partial pad 122 and a second partial pad 124, wherein at least a portion of the first partial pad 122 and at least a portion of the second partial pad 124 overlap.

The lower substrate 110 may be a known substrate for displaying images in liquid crystal display devices or organic electroluminescent display devices. The lower substrate 110 may be formed of glass, plastic, etc. The display element disposed on the lower substrate 110 may include known configurations such as a thin film transistor (TFT), a pixel electrode, a liquid crystal layer and/or an organic light emitting element, etc.

The cover glass 310 may be a known substrate disposed to cover the lower substrate 110 and for protecting the lower substrate from dust, oxygen, moist, or other physical elements. The cover glass may be formed of glass, plastic, etc.

The pad 120 may be interposed between and along the periphery of the lower substrate 110 and the cover glass 310. The pad 120 (e.g., sealing member) may provide waterproof and dustproof functions by sealing a space between the lower substrate 110 and the cover glass 310. Further, the pad 120 in the display device 100 may serve to attach together the lower substrate 110 and the cover glass 310.

Hereinafter, the description is made mainly with respect to the display device in which the pad 120 is disposed on the lower substrate 110 and the cover glass 310 is disposed on the pad 120. The term “on” refers to “upper position in a cross-sectional view”. However, here, the upper position serves merely to explain relative positional relations between configurations on the basis of the lower substrate as the lower position, and thus is not limited to necessarily being on the upper position in a vertical direction.

In an embodiment, the term “disposed along a periphery” refers to being disposed on a boundary portion of the substrate and parallel to an edge. FIG. 1 illustrates that the pad 120 according to an embodiment is disposed along the periphery of the lower substrate 110.

The pad 120 mainly refers to a whole layer disposed all around the periphery, and the respective parts of the pad 120 is mainly referred to as partial pads 122, 124, 126 and 128, but one individual partial pad as a pad component may also be referred to as “pad” as necessary. A person skilled in the art can clearly understand whether the term “pad” refers to a whole of the pad or a partial pad based on the drawings and the description of the present disclosure.

The pad 120 may have a considerable thickness to serve to prevent or at least reduce penetration of air, dust, water, etc. into a space between the lower substrate 110 and the cover glass 310, and may have a thickness of at least 0.1 mm in one embodiment. For a display device capable of touch input processing, a thickness of several millimeters or less is preferable.

Further, the pad 120 may include a material having an adhesive property in order to serve to attach the lower substrate 110 and the cover glass 310 together. In an embodiment, the pad 120 may include a pad layer having an interfacial adhesive property. The pad 120 may be attached to the lower substrate 110 under the pad and to the cover glass 310 on the pad, thereby may serve to support the display device 100.

The pad 120 may include preferably a closed-cell foam acrylic adhesive (hereinafter, referred to as an “acrylic adhesive”) in one embodiment. The acrylic adhesive may have a waterproof property, also have an inherently adhesive property, and may be elastically deformable based on its excellent elasticity. In addition, the acrylic adhesive may be adhered in an elastically-deformed state. For example, the pad may include the acrylic adhesive and have a density of 0.8 to 1.0 g/cm, but is not limited thereto.

The pad 120 may be a single layer or may have a multilayer structure having another layer. For example, the pad 120 may be configured of a single pad layer including an acrylic adhesive, or may further include a substrate layer in order to increase an attachment strength with the lower substrate 110 and the cover glass 310. The pad layer may occupy 50% to 100% of a total thickness of the pad in one embodiment, but is not limited thereto. Here, the “thickness” refers to a length of a layer in a cross-sectional view.

According to an embodiment, the pad 120 may be formed in a combining-type. Here, the term “pad in a combining-type” is a concept distinguished from a pad in a single-piece type, and refers to a way in which a plurality of partial pads in pieces are combined to form a whole of the pad or a pad produced as such. That is, a combining-type pad is a way of forming a pad by combining the partial pads. For example, the pad may include the first partial pad and the second partial pad.

As described above, the conventional technique of producing a sealing element in a single-piece type is disadvantageous in terms of costs as it causes a large waste of the discarded material and the low production efficiency.

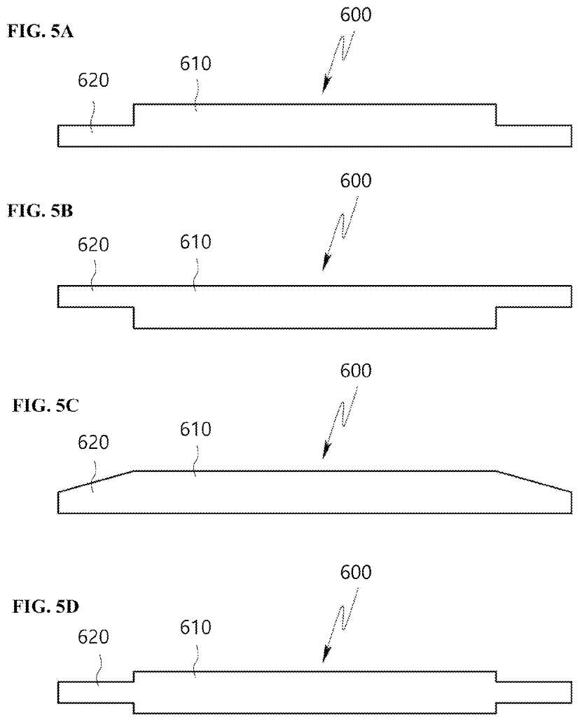

However, the method of producing a pad in a combining-type has an excellent effect of improving the pad production efficiency compared to the manufacturing of a single-piece type pad. Specifically, the method of producing a combining-type pad can provide a larger plurality of pads from a pad material compared to a single-piece type pad and can significantly reduce the amount of material discarded wastefully. For example, through the method of mass producing a pad from a pad material in the shape shown in FIG. 5A, highly improve production efficiency can be achieved. As a result, the method of producing a combining-type pad has an effect of reducing costs involved in producing the pads and therefore the display device.

In addition, the method of producing a combining-type pad has an advantage of allowing the pad to have various shapes. The method of producing a combining-type pad can provide an additional advantageous effect by varying the shape of the partial pads or the combining structure between the partial pads. There will be described various shapes and combining structures of the partial pads in various embodiments.

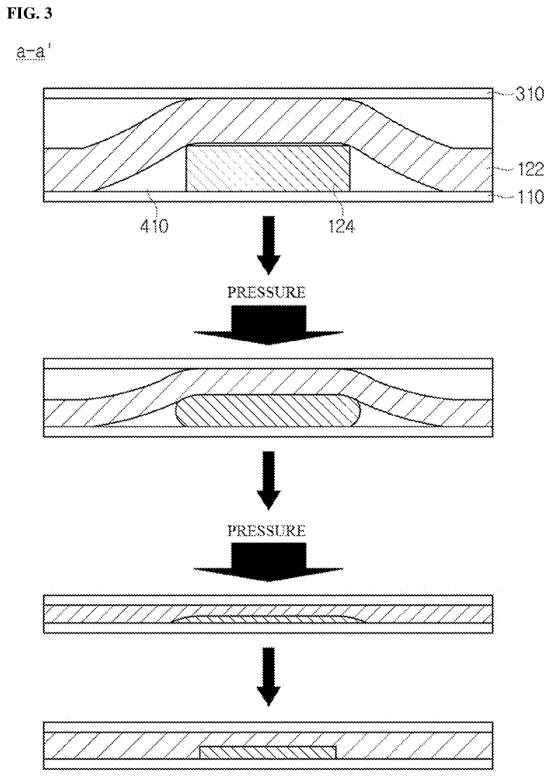

Referring to FIG. 3, there is described overlapping of partial pads according to the present disclosure.

FIG. 3 is a cross-sectional view illustrating an overlapping area of the partial pads of the display device according to an embodiment of the present disclosure, and corresponds to a cross-sectional view taken along a-a′ of the enlarged view of FIG. 1. In an embodiment, in the pad 120, a plurality of the partial pads are configured to be combined by overlapping the plurality of partial pads. For example, the pad 120 is configured such that at least a portion of the first partial pad 122 and at least a portion of the second partial pad 124 overlap. Here, the term “overlap” refers to a state in which one pad is on the other pad in a layered structure of the display device. The term “layered structure” refers to a structure in which the lower substrate 110, the pad 120 and the cover glass 310 are stacked up in layers in a cross-sectional view.

One partial pad may be disposed on the other partial pad as to overlap. FIG. 3 illustrates a view of overlapping of the first partial pad 122 on the second partial pad 124, but this is exemplary and the order of the arrangement therebetween may be reversed.

The pad has a predetermined thickness and thus may be deformed to be flattened in a width when being compressed by pressure. Hereinafter, the state as such is referred to as “being deformed”. As shown in FIG. 2, the pad 120 is deformed when compressing the lower substrate 110 and the cover glass 310. According to an embodiment, the pad 120 may be formed of a single pad including an acrylic adhesive, and be flattened while increasing in a width by a length corresponding to 20% of the thickness under the pressure of 0.42 MP in the area of 1.88 cm². The pad layer may be deformed to various degrees according to a composition of the included acrylic adhesive, pad thickness, etc.

As shown in FIG. 3, when the first partial pad 122 and the second partial pad 124 overlap, a gap 410 may occur between the first partial pad 122 and the second partial pad 124 due to the thicknesses of the partial pads. Air or the like may pass though the gap 410.

When pressure is applied as to compress the lower substrate 110 and the cover glass 310, the first partial pad 122 and the second partial pad 124 may be deformed. As the applied pressure increases, the degree of the deformation may be greater.

When the degree of the deformation is sufficiently great, the first partial pad 122 and the second partial pad 124 may be deformed enough to contact each other at the gap 410 and thereby fill the gap 410. Since each of the partial pads has an adhesive property, the first partial pad 122 and the second partial pad 124 may contact at the gap 410 and be adhered to each other. Therefore, even when deformation recovery occurs upon pressure being removed, the first partial pad 122 and the second partial pad 124 still stay adhered to each other, and the gap 410 may remain filled. As a result, the cross-section of the pads adhered to each other may form a complete barrier without any gap therein, from which waterproof and dustproof functions can be secured. Furthermore, there may be almost no difference in height between the portion where the overlapping is performed and the portion where the overlapping is not performed in the display device.

A method of arranging the combining-type pads merely to be close to each other as possible without any overlapping therebetween may cause a gap due to mechanical and physical limitations. A method of manually aligning the pads to be in contact side by side generally occurs a gap of about 0 to 0.3 mm, which results in deterioration in waterproof and dustproof performances. In the display device according to various embodiments of the present disclosure, superior waterproof and dustproof protection may be secured by disposing the pads overlappingly, compared to disposing the combining-type pads merely to be in close contact.

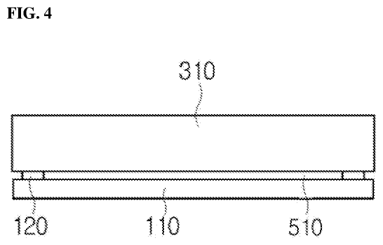

FIG. 4 is a cross-sectional view illustrating an air gap 510 during a manufacturing process of the display device according to an embodiment of the present disclosure.

Referring to FIG. 4, there is described an air gap 510 between the lower substrate 110 and the cover glass 310 according to an embodiment.

Referring to FIG. 4, the lower substrate 110, the cover glass 310, the pad 120 disposed between the lower substrate 110 and the cover glass 310, and the air gap 510 are shown.

The display device according to an embodiment of the present disclosure may reduce an air gap 510 generated in manufacturing of the display device by configuring a type of the pad disposed between the lower substrate 110 and the cover glass 310 to be a combining-type. In more detail, the display device may allow air to escape through the gap 510 in the process of overlapping and compressing of the pad 120, and thus may maintain the air gap 510 at an appropriate level. The air gap 510 refers to a certain air layer which is formed between the lower substrate and the cover glass by disposing the pad 120 on the boundary of the substrate, and although the air gap 510 cannot be completely eliminated, it needs to be maintained not excessively and in an appropriate level. The pressure and speed for the compressing process of the display device may be adjusted so that air sufficiently escapes through the gap 510.

A conventional technique has a problem that while air is contained in the process of placing a single-piece type sealing member on a substrate and adding a cover substrate thereto, the air cannot escape due to the single-piece type sealing member, with generating an excessive air gap bulging in the display device. For this reason, the conventional display device may have a problem of having a poor finish of the product, and also the excessive air gap 510 causes a problem, particularly in a panel capable of a touch input, of deteriorating the touch function.

The display device according to the present disclosure in which the combining-type pads are overlappingly disposed can provide a solution to the conventional problem of the excessively formed air gap. That is, the display device including the overlappingly disposed combining-type partial pads may have improved pad production efficiency and also exhibit excellent waterproof and dustproof characteristics by the improved sealing effect, and may minimize an air gap to a needed level.

Embodiments of Protruding Portion

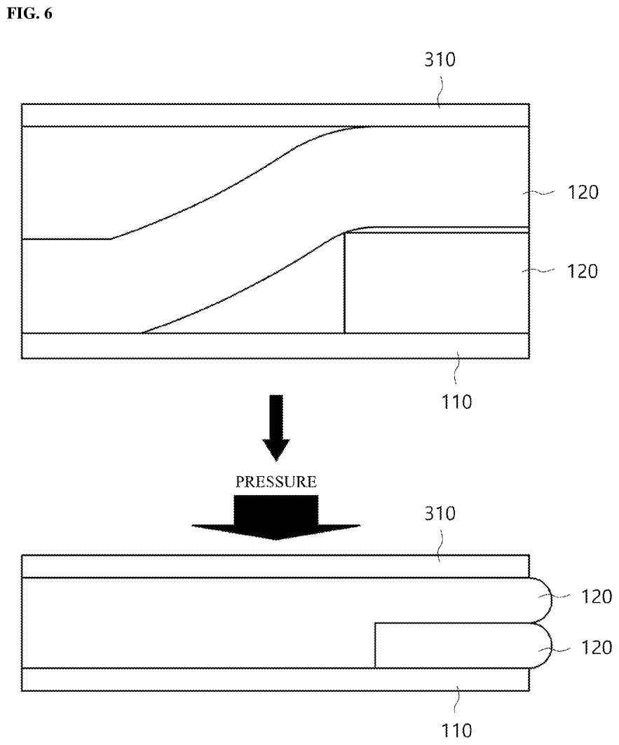

Referring to FIGS. 5A to 5D and 6, there are described various embodiments of the partial pad of the present disclosure.

FIGS. 5A to 5D shows top plan views of examples of various shapes of the partial pad according to an embodiment of the present disclosure. In an embodiment, a partial pad 600 may have a center portion 610 and a protruding portion 620. For example, the first partial pad may have a first center portion and a first protruding portion, and the second partial pad may have a second center portion and a second protruding portion.

The center portion 610 is a portion having a relatively larger width in the pad and corresponds to a body of the pad, and may play a great role in attaching the lower substrate and the cover glass and supporting the display device. Here, the width corresponds to a length in plan view and refers to a vertical length in FIG. 5. The protruding portion 620 may be configured to be on a side surface of the center portion 610 and may have a width that is smaller than a width of the center portion 610. That is, the protruding portion 620 extends from the center portion 610.

According to an embodiment, the first partial pad may include a first center portion and a first protruding portion having a width smaller than a width of the first center portion, and the second partial pad may have a second center portion and a second protruding portion having a width smaller than a width of the second center portion. Furthermore, the pad may be configured such that at least a portion of the first protruding portion and at least a portion of the second protruding portion overlap.

Since the portion where the pads overlap may be flattened while increasing in a width when being compressed, it may disturb adhesion of around portions or its adhesion may be disturbed by the around portions. Also, if the overlapping is performed throughout a too large area, the pad 120 may be excessively recovered from the deformation when pressure is removed after finishing the compressing process, which causes lifting vertically of the display device. Accordingly, the overlapping area needs to be formed with a reasonable size within a size range securing waterproof and dustproof functions.

The pads overlapping at the narrow protruding portions can be, when being compressed, flattened in a width sufficiently, which provides an effect of having the lower substrate 110 and the cover glass 310 ideally being compressed without any difference in height.

Since the portion where the pads overlap is flattened while increasing in a width when being compressed, it may protrude to the outside of the lower substrate 110 or the cover glass 310 in a cross-sectional view.

Referring to FIG. 6, the pad 120 may protrude to the outside of the lower substrate 110 when the partial pads overlap on the outermost boundary of the lower substrate. The portion protruding to the outside may deteriorate the aesthetics and cause the bezel of the display device to become large.

In an embodiment, the pad 120 may be configured to have a concave area at one or more corners in a plan view so as not to protrude to the outside of the substrate.

In FIG. 5A, the protruding portion of the partial pad is in the shape in which the upper end of the partial pad is retracted. When the partial pad is configured as such, one or more concaves area may be formed at a corner where the partial pads are combined to each other. FIG. 1 illustrates that a concave area 140 is formed at the corner. As a result, an innermost outer edge of the first partial pad 122 or an innermost outer edge of the second partial pad 124 does not respectively extend past an outermost outer edge of the first partial pad 122 or an outermost outer edge of the second partial pad 124 in a plan view of the display device after compression of the lower substrate 110, the pad 120, and the cover glass 310.

In FIG. 5B, the protruding portion of the partial pad is in the shape in which the lower end of the partial pad is retracted, and in this case, a concave area is not formed at the corner where the partial pads are combined, and the pads may protrude to the outside when being overlapped. Therefore, the shape of the partial pad according to either FIG. 5A, 5C or 5D, which can form a concave area at the corner of the pads when being combined, is more advantageous than the shape of FIG. 5B. When the shape of the protruding portion is configured as such, the pad does not protrude to the outside of the substrate and therefore has a good finish.

Recently, the so-called zero (0) bezel, in which the bezel size is reduced, is attracting much attention in all display device areas from small devices such as mobile phones as well as medium-sized devices such as tablets to large devices such as TVs. In order to implement the zero bezel, the display device has a portion for bonding or sealing on an outermost boundary of an edge portion of the substrate. If the pad is disposed not to protrude to the outside of the substrate even after being compressed, the display device may be better in a design perspective and avoid unnecessary increase of the bezel size.

Arrangement of Partial Pads

Referring to FIGS. 5A to 5D and 7 to 9, there are described various embodiments of a shape of the partial pad and an arrangement of the partial pads according to the present disclosure.

Referring to FIGS. 5A to 5D, there is described an I-shaped partial pad. In an embodiment, the partial pad 600 may be formed in an I-shape.

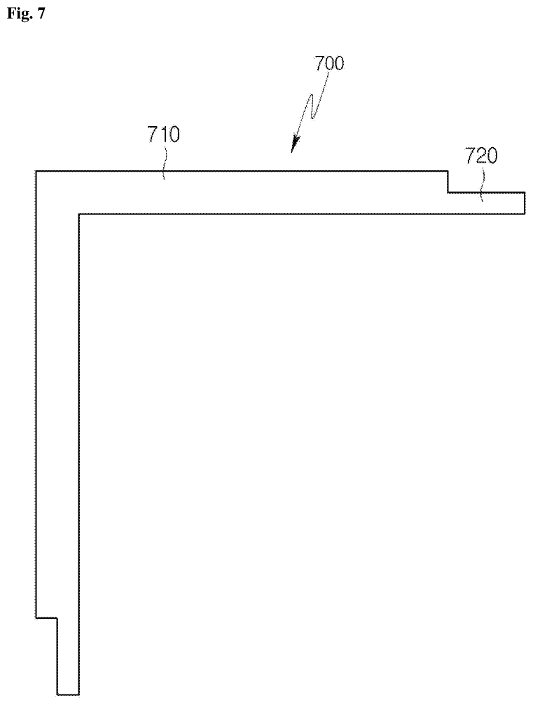

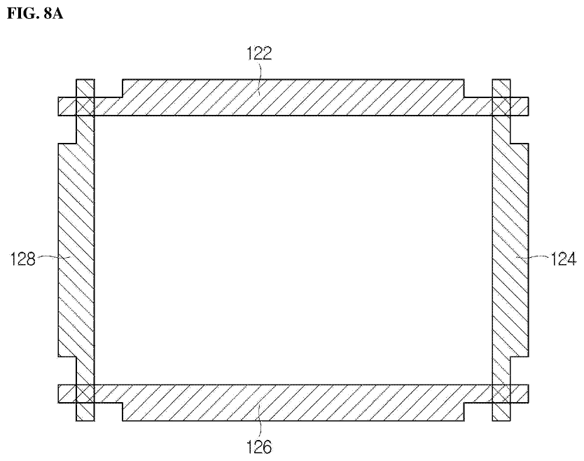

Referring to FIG. 7, there is described an L-shaped partial pad 700. In another embodiment, the partial pad may be formed in an L-shape. For example, an L-shaped partial pad 700 may has an L-shape with a center portion 710 being bent, and a protruding portion 720 may be provided at both ends thereof.

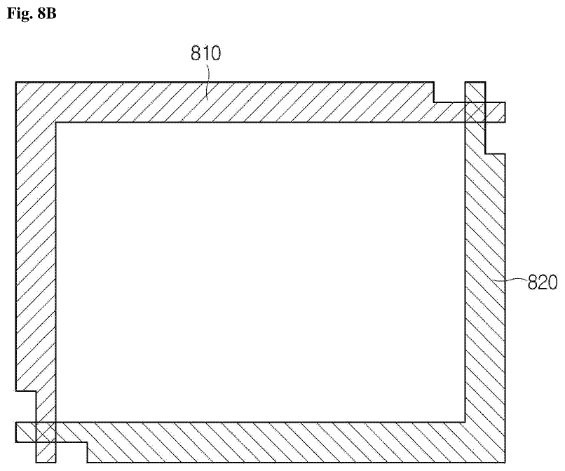

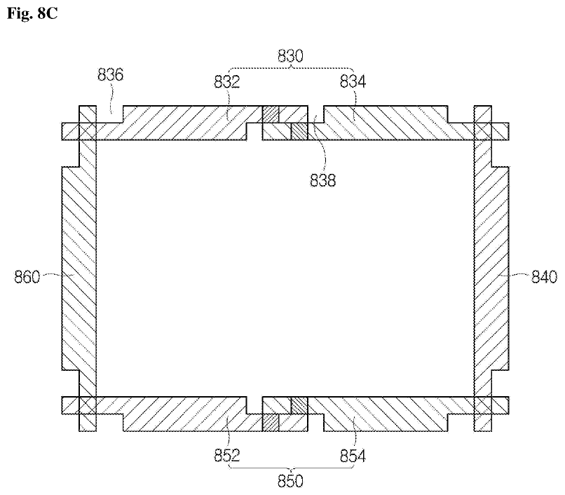

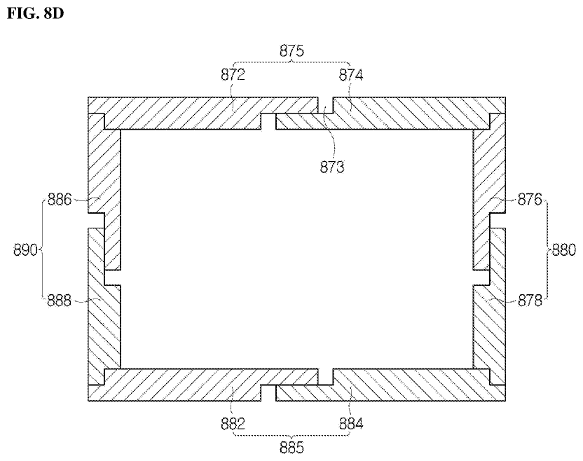

Referring to FIG. 8A, there is described an arrangement of the partial pads on the lower substrate 110 of the present disclosure. The partial pads may have various arrangements. The lower substrate 110 is not illustrated in FIG. 8A. According to an embodiment, the I-shaped partial pads may be respectively disposed on the upper portion, the lower portion, the left side portion, and the right side portion of the lower substrate 110. FIG. 8A shows a top plan view illustrating that the first partial pad 122 is on the upper portion, the second partial pad 124 on the right side portion, the third partial pad 126 on a lower portion, and the fourth partial pad 128 on a left side portion of the lower substrate.

In an embodiment, the first partial pad 122 and the second partial pad 124 may meet at the corner of the upper right side portion. The portion where the pads meet may be where they overlap, which forms an overlapping area 130. The term overlap (ping) refers to the same as described above.

In the present disclosure, the terms “upper portion, left side portion, right side portion, and lower portion” may explain relative positional relations. Any one of the upper portion, left side portion, right side portion and lower portion is expressed as an edge portion. The term of upper portion may refer to a portion at the top side, the term of lower portion referring to a portion at the bottom side, and the term of one side portion referring to a portion either at the left side or at the right side, in plan view of the lower substrate. The corner may refer to, in a rectangle corresponding to the shape of the lower substrate of FIG. 1, a vertex or vicinity thereof where the partial pads are combined. Also, in the present disclosure, the terms “upper, left, right, and lower” may indicate directions. The term “upper” may refer to a direction directed to the top side based on a horizontally long rectangular display device as a reference.

Although the present disclosure is mainly described based on a horizontally long rectangle, which is a general shape of a display device, but is not necessarily limited thereto, and since the display device may have a vertically long shape, directions and portions may be appreciated by various embodiments based on a reference. For example, if the first partial pad is disposed on the upper portion and the second partial pad is disposed on the right side portion, a person skilled in the art easily recognize the first partial pad on the right side portion and the second partial pad on the lower portion as having a same phase when rotated 90 degrees clockwise, and it should be appreciated the expressions herein embrace such concepts.

Referring to FIG. 8B, there is described an arrangement of an L-shaped partial pad according to one embodiment. FIG. 8B is a top plan view illustrating a partial pad according to another embodiment of the present disclosure. In FIG. 8B, the lower substrate 110 is not illustrated. In an embodiment, a first partial pad 810 may be disposed to extend from the upper portion the left side portion of the lower substrate, and a second partial pad 820 may be disposed to extend from the right side portion to the lower portion of the lower substrate. Here, the term “disposed to extend” refers to an arrangement to cover two or more edge portions by the L shape. If any one of the left side portion and the right side portion is referred to as one side portion, the other one may be referred to as an opposite side portion of the one side portion.

When the partial pad is L-shaped, the pad may achieve the desired effect intended by the combining-type pads and the overlapping arrangement of the combining-type pads with just two overlapping areas.

FIG. 8C illustrates a pad according to another embodiment of the present disclosure. A first partial pad 830, a second partial pad 840, a third partial pad 850, and a fourth partial pad 860 are respectively disposed on the upper portion, the right side portion, the lower portion and the left side portion of the lower substrate, and the first partial pad 830 and the third partial pad 850 disposed on the long edges may include a plurality of sub-partial pads. That is, the first partial pad 830 may include two sub-partial pads 832 and 834, and the third partial pad 850 may include two sub-partial pads 852 and 854. Here, the term “sub-partial pad” is used, when a partial pad includes a plurality of partial pads, to distinguishingly refer to the plurality of partial pads. When describing the relation between the sub-partial pads, those may be referred to as the partial pads. The pad 120 may include grooves 836 and 838 formed by combining of the partial pads or the sub-partial pads.

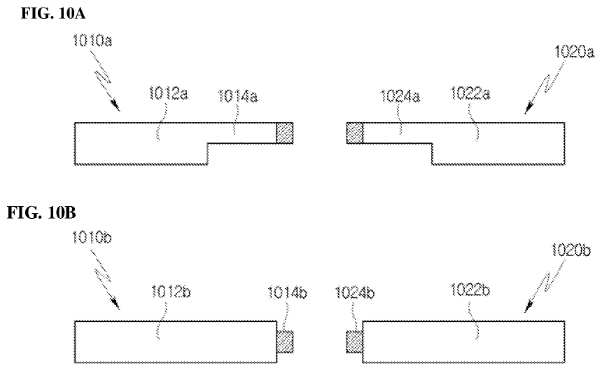

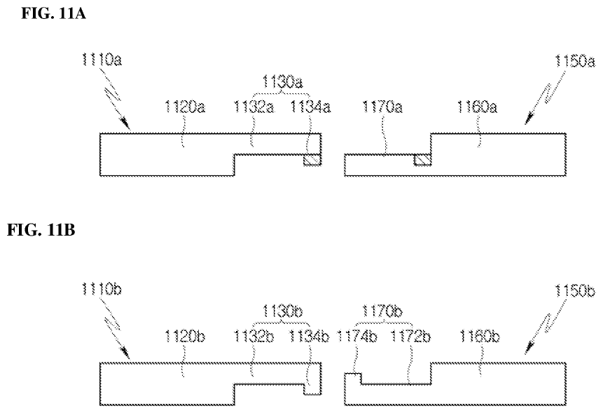

If the size of the partial pad becomes smaller, there is an advantage in production. An embodiment in which a plurality of small-sized partial pads are disposed to be combined at the middle portion of an edge portion will be described in detail referring to FIGS. 10A, 10B, 11A, 11B and 12.

FIG. 8D illustrates a pad according to another embodiment of the present disclosure. A first partial pad 875, a second partial pad 880, a third partial pad 885, and a fourth partial pad 890 are respectively disposed on the upper portion, the right side portion, the lower portion and the left side portion of the lower substrate, and may respectively include a plurality of sub-partial pads. For example, the first partial pad 875 may have a structure of combining two sub-partial pads 872 and 874, the second partial pad 880 having a structure of combining two sub-partial pads 876 and 878, and the third partial pad 885 having a structure of combining two sub-partial pads 882 and 884, and the fourth partial pad 890 having a structure of combining two sub-partial pads 886 and 888.

The partial pad or the sub-partial pads may be disposed to be in contact with another. For example, the sub-partial pads 872 and 874 of the first partial pad 875 are disposed to be in contact with each other at the middle portion of the upper portion. The partial pad or the sub-partial pads may be disposed to form a groove 873.

The pad 120 may include the groove 873. The groove 873 may refer to an empty space (e.g., a gap) in the plan view, which is formed when the partial pads or the sub-partial pads are combined. The groove 873 may provide various effects such as allowing an effective application of a resin thereto and the like.

The first partial pad 875 and the second partial pad 880 may be disposed to share more than two contacting edges at the corner. FIG. 8D illustrates that the first partial pad 875 and the second partial pad 880 share the three contacting edges of the respective outer boundaries from the protruding portion to the body portion. The partial pads combined with each other at the respective corners may be disposed to share more than two contacting edges.

When the partial pads are disposed to share several contacting edges, the possibility of generating a gap through which dust or the like can penetrate in the attaching process of the partial pads can be significantly reduced. Even if one edge fails to be in complete contact and a gap occurs, the waterproof and dustproof performance can be secured if the other edge is in a complete contact. Also, since the plurality of edges may be different in direction such as being bent by 90 degrees, the waterproof and dustproof effects can be improved.

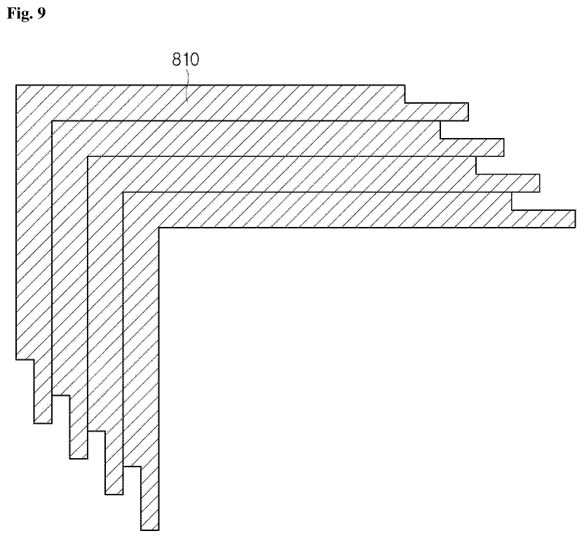

FIG. 9 illustrates a manufactured form of the partial pad according to an embodiment. The manufactured form of the L-shaped partial pad has a manufacturing advantage that can reduce the discarded portions because it can be produced in the form of the several L-shape pads stacked.

Furthermore, while using the I-shaped partial pad requires four combining at the four corners, the L-shaped partial pad allows reducing the processing for the disposing, overlapping and compressing steps to the two times while achieving the desired waterproof and dustproof protection, and is convenient when assembling. In particular, since the bent portion is manufactured to be sealed, the display device according to the present embodiment has high reliability of the waterproof and dustproof effects compared to the structure of overlapping and combining the partial pads at the four corners.

A mixed form of an L-shaped partial pad and an I-shaped partial pad is also possible. For example, the pad may be configured such that the four sides are surrounded by one L-shaped partial pad and two I-shaped partial pads. A method of arranging the pads may be appropriately selected in consideration of the advantages in manufacturing and sealing effect.

That is, the display device having the L-shaped partial pad is advantageous in production by reducing the number of the processing for the disposing, overlapping and compressing steps, while having more excellent waterproof and dustproof effects.

Referring to FIGS. 10A, 10B, 11A, 11B and 12, there is described an embodiment in which the partial pads are combined on a middle portion of one edge portion. In FIGS. 10A, 10B, 11A, 11B and 12, the hatched lines indicates that the portions with the hatched lines can overlap with each other. In FIGS. 10A, 10B, 11A, 11B and 12, the lower substrate is not illustrated, and in order to intensively describe the portion where the partial pads are combined, other pad portions or other portions of the partial pad may be shown as being omitted.

First, a description of FIGS. 10A to 10B will be made. In an embodiment, first partial pads 1010a and 1010b may be disposed on the left side of the upper portion of the lower substrate 110, and second partial pads 1020a and 1020b may be disposed on the right side of the upper portion of the lower substrate 110. Further, the first partial pads 1010a and 1010b and the second partial pads 1020a and 1020b may be combined at the middle portion of the upper portion of the lower substrate.

Here, one side of the upper portion and the other side of the upper portion may correspond, for example, the left side of the upper portion and the right side of the upper portion. Alternatively, it may be a position having the same phase. That is, in the case of a vertically long display device, it may be appreciated as the lower side of the left side portion and the upper side of the left side portion, or the upper side of the right side portion and the lower side of the right side portion. In this case, the first partial pad and the second partial pad may be combined at the middle portions of the left side portion and the right side portion, respectively.

For a large display device such as a TV, when a single partial pad is disposed on one edge portion, the size of the partial pad should be very large. Disposing a single partial pad on one edge portion may be disadvantageous in the manufacturing process of the partial pad as it requires material larger than the partial pad size, and be inconvenient to attach the partial pad to the lower substrate.

A pad according to an embodiment may be configured such that the partial pads are overlappingly combined with each other, on one edge portion, particularly, on a long edge portion such as the upper portion or the lower portion. In a case where the long edge portion has an arrangement of combining several partial pads, it is possible to produce the partial pad with a material smaller than the length of the display device, which is advantageous for production.

First, a description of FIG. 10A will be made. According to an embodiment, a first partial pad 1010a includes a first center portion 1012a and a first protruding portion 1014a, and the second partial pad 1020a includes a second center portion 1022a and a second protruding portion 1024a. Furthermore, at least a portion of the first protruding portion 1014a and at least a portion of the second protruding portion 1024a may overlap.

The protruding portions 1014a and 1024a may be configured to have a width that is less than a width of the center portions 1012a and 1022a. An end of the first protruding portion 1014a and an end of the second protruding portion 1024a may overlap with each other. In FIG. 10A, the portions where the first protruding portion 1014a and the second protruding portion 1024a overlap with each other are indicated with hatched lines.

Next, a description of FIG. 10B will be made. According to an embodiment, a first partial pad 1010b may include a first center portion 1012b and a first protruding portion 1014b, and a second partial pad 1020b may include a second center portion 1022b and a second protruding portion 1024b. Also, the first protruding portion 1014b and the second protruding portion 1024b may overlap with each other. In FIG. 10B, the portions of the first protrusion 1014b and the second protrusion 1024b with each other are indicated by hatched lines.

In the embodiment according to FIG. 10A, it is embodied that the protruding portions 1014a and 1024a at least partially overlap, and in the embodiment according to FIG. 10B, it is embodied that the protruding portions 1014b and 1024b entirely overlap. As such, a barrier can be formed, when the pad is compressed, with the protruding portions 1014a, 1024a, 1014b, and 1024b overlapping. Through this, it is possible to secure waterproof and dustproof functions capable of preventing dust or moisture flowing from an outside.

In FIGS. 10A and 10B, there is illustrated an embodiment in which the protruding portions overlap laterally. Overlapping laterally means that the first protruding portions 1014a and 1014b of the partial pad and the second protruding portions 1024a and 1024b of the partial pad meet on their left and right sides with respect to the overlapping area. In contrast thereto, an embodiment in which the protruding portions overlap vertically will be described below referring to FIGS. 11A and 11B.

Referring to FIG. 11A, a first protruding portion 1130a according to an embodiment may be configured to include a first body portion 1132a and a first protrusion 1134a protruding upward (e.g., a first direction) or downward (e.g., a second direction opposite the first direction) away from the first body portion 1132a in plan view, in that the first protrusion 1134a and at least a portion of a second protruding portion 1170a overlap.

As described referring to FIGS. 10A and 10B, the protruding portions may overlap laterally, and as described referring to FIGS. 11A and 11B, the protruding portions may overlap vertically. However, overlapping laterally and overlapping vertically are not mutually exclusive, and therefore overlapping laterally and vertically may be implemented, which also secure the effect as same with overlapping vertically.

When the partial pads overlap at the middle portion of one edge portion, as for the overlapping direction, overlapping vertically is more advantageous than overlapping laterally. Referring to FIGS. 3, 10A, 10B, 11A and 11B together, when the partial pads overlap laterally, the gap 410 is exposed to the outside of the lower substrate. To the contrary, when the partial pads overlap vertically, the gap 410 is not exposed to the outside by the body portion 1132a of the partial pad. Accordingly, the waterproof and dustproof performances of the pad may be further improved.

Accordingly, in an embodiment, at least one protruding portion may have a protrusion protruding upward and downward to vertically overlap with a protruding portion at the other direction. For example, as shown in FIG. 11A, the first protruding portion 1130a may have a first protrusion 1134a protruding downward as to vertically overlap with the second protruding portion 1170a. The body portion may be the remaining portion of the protruding portion excluding the protrusion. For example, the first protruding portion 1130a may include the first protrusion 1134a and the first body portion 1132a. The positional relation between the first protruding portion and the second protruding portion and the position of the protrusion may vary. The protruding portion at the upper position in plan view may be combined via its protrusion protruding downward, or a protruding portion at the lower position in plan view may be combined via its protrusion protruding upward.

Referring to FIG. 11B, a first protruding portion 1130b may include a first body portion 1132b and a first protrusion 1134b, and a second protruding portion 1170b may include a second body portion 1172b and a second protrusion 1174b. According to an embodiment, the protruding portions 1130b and 1170b include the respective protrusions 1134b and 1174b, and each of the protrusions may be combined with the protruding portion at the other direction. In an embodiment according to FIG. 11B, the first protrusion 1134b of the first protruding portion 1130b may be combined with the second body portion 1172b, and the second protrusion 1174b of the second protruding portion 1170b may be combined with the first body portion 1132b. Referring to FIG. 8C together, a first partial pad 1110b and a second partial pad 1150b of FIG. 11B may be combined in a way as shown in the upper portion of FIG. 8C. In FIG. 8C, the overlapping portions are indicated by the distinguishable hatched lines.

As shown in FIG. 11B, when each of the partial pads is configured to have a protrusion and be combined with the partial pad from the other direction, the combining strength between the partial pads is increased, and the pad may be more firmly combined. In addition, since a double barrier is formed through the combining arrangement, the pad may have more excellent waterproof and dustproof capabilities. As the number of the protrusions increases and thus the number of the portions where the overlapping is performed increases, the pad may have improved combining strength and waterproof and dustproof effects.

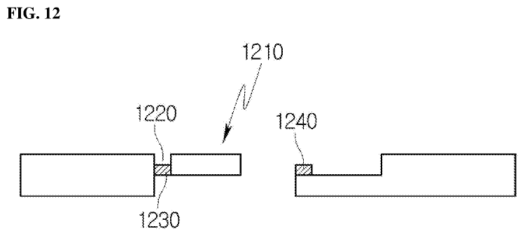

Referring to FIG. 12, there is described an embodiment of a combining arrangement of a pad having a concave portion. FIG. 12 provides a top plan view illustrating a configuration of a protruding portion of a partial pad having a concave portion according to one embodiment of the present disclosure.

According to an embodiment, a protrusion 1240 is configured to protrude upward of the body portion of the second protruding portion, a first protruding portion 1210 may include a concave portion 1220 and an overlapping portion 1230 formed under the concave portion 1220 in a plan view, and the pad may be configured such that the protrusion 1240 and the overlapping portion 1230 overlap. In an embodiment, the concave portion 1220 refers to a portion having a concave shape formed by being retracted from the outer boundary of the protruding portion (e.g., a concave portion that extends into the first protruding portion 1210), and the overlapping portion 1230 refers to a portion where the protruding portion from the other direction or the protrusion 1240 of the protruding portion is overlapped. In one embodiment, the overlapping portion 1230 is formed under the concave portion 1220 in a plan view.

The concave portion 1220 serves to secure an area for the pads being flattened while increasing in a width to a sufficient degree when the pads overlap at the overlapping portion 1230 and are deformed. The pad having the concave portion 1220 does not protrude to the outside of the substrate even when overlapping, and the sufficient deformation is allowed in the overlapped area.

The positions of the concave portion 1220 and the overlapping portion 1230 may be configured to vary on the protruding portion. In one embodiment, the protruding portion at the upper position in a plan view has the concave portion 1220, but not limited thereto. When the protruding portion at the lower position in plan view has the concave portion, the overlapping portion may be formed on the concave portion in plan view. According to another embodiment, the protrusion may be configured in a form which is vertically, horizontally or origin symmetrical to that shown in FIG. 12.

Layered Structure of the Pad

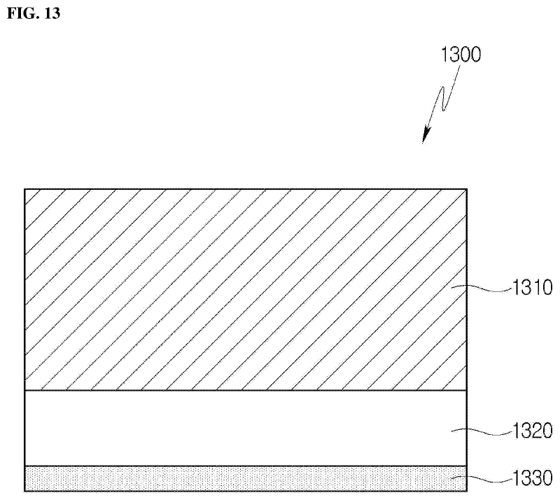

Referring to FIGS. 13, 14, 15, 16A and 16B, there is described an embodiment related to the layered structure of the pad.

The pad may be formed of a single pad layer including an acrylic adhesive or the like. According to another embodiment, the pad may be formed of multilayers further including a layer including other substrates.

FIG. 13 is a cross-sectional view illustrating a multilayered pad according to an embodiment of the present disclosure.

A pad 1300 according to an embodiment may include a substrate layer 1320 and a pad layer 1310. When the substrate layer 1320 does not have an adhesive property, the pad may further include an adhesive layer 1330 under the substrate layer 1320. Here, the adhesive layer 1330 is a configuration adapted to adhere the substrate layer 1320 to another layer or substrate. Even if the adhesive layer 1330 is not illustrated in the drawings or the description for the adhesive layer 1330 is not provided while describing that the substrate layer 1320 is adhered to another layer or substrate, it may be appreciated that the pad layer has the adhesive layer 1330 for adhesion of the substrate layer 1320.

The substrate layer 1320 is a layer having different property from the pad layer 1310 and therefore may exhibit an additional function. For example, the substrate layer may include PET having a more rigid property than the pad layer. In this case, the substrate layer 1320 may improve the yield in pad manufacturing and improve the dimensional stability of the pad. In addition, the substrate layer 1320 may improve the attaching workability of the pad. In an embodiment, the substrate layer has an advantage of compensating for dimensional changes or errors occurring due to the stretching and deformation when the pad is formed of the pad layer 1310 only.

When the pad is formed of multiple layers, the overlapping way of the partial pads at the portion where the partial pads overlap may be important. It may be important to arrange the pad layers of the partial pads to be in contact with each other.

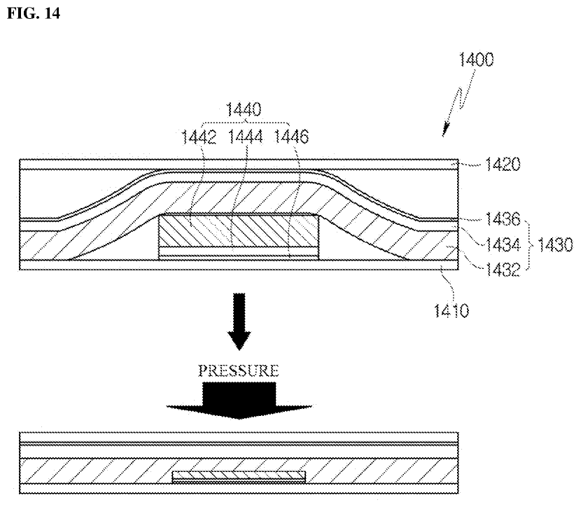

FIG. 14 is a cross-sectional view illustrating an overlapping area of the multilayered pads according to an embodiment of the present disclosure. A display device 1400 according to an embodiment includes, in an area where a first partial pad 1430 and a second partial pad 1440 overlap, the second partial pad 1440 may include a second substrate layer 1444 in contact with a lower substrate 1410 and a second pad layer 1442 disposed on the second substrate layer 1444, and the first partial pad 1430 including a first substrate layer 1434 in contact with a cover glass 1420 and a first pad layer 1432 disposed under the first substrate layer 1434 and on the second pad layer. Here, the terms “in contact with a lower substrate” or “in contact with a cover glass” refer to being adhered through adhesive layers 1446 and 1436.

As shown in FIG. 14, in the case of disposing the pad layers to be in contact with each other, the two pad layers may be deformed by compression and therefore fill a gap between the pad layers. Through this, the display device may sufficiently achieve the various effects as described above with respect to the single-layer pad, and also have additional effects brought by the substrate layer such as improved combining strength with the substrate.

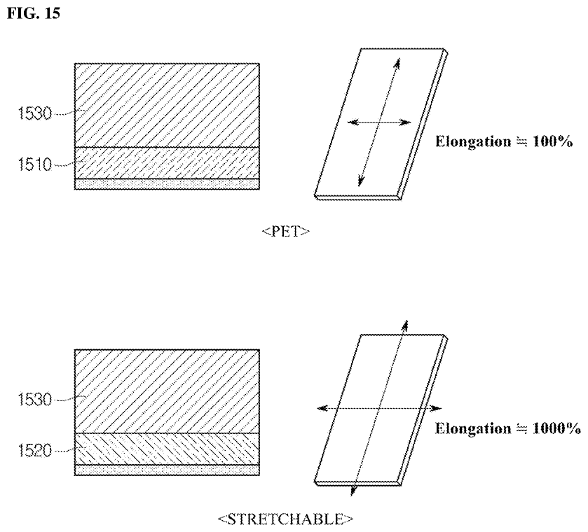

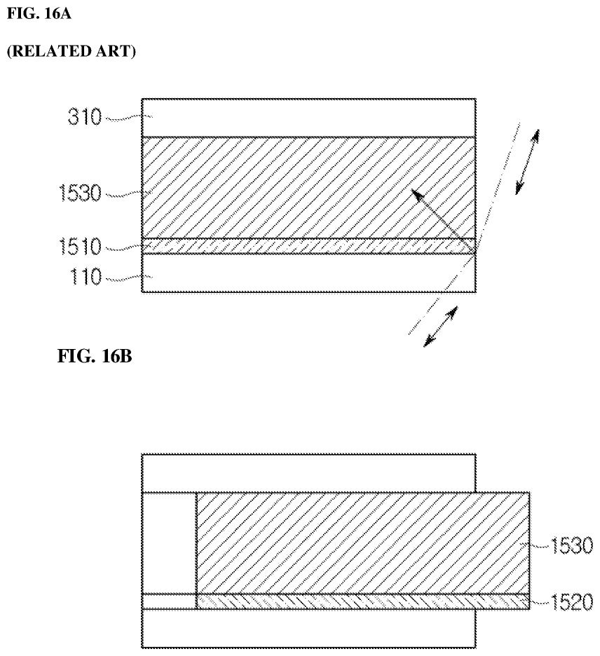

Referring to FIGS. 15, 16A and 16B, there is described a substrate layer 1520 including a stretchable substrate.

FIG. 15 is a view showing the properties of the stretchable material layer and the PET substrate layer of the present disclosure. The substrate layer may include a substrate having a stretchable property. Here, the term “stretchable” refers to the capability to extend to an elongated length by tension. A substrate layer 1510 including a PET substrate may have an elongation of about 100%, whereas the substrate layer 1520 including the stretchable substrate may have an elongation of about 1000%. For example, the stretchable substrate may include a polyurethane film (TPU).

FIGS. 16A and 16B illustrates reworking of the display device according to the respective substrate layer of the present disclosure. According to the conventional method for separating pad layers, when the substrate layer is rigid such as the PET material, it can be carried out by inserting a thread between the layers moving it laterally back and forth to separate the substrate layer from either the lower substrate or the cover glass, as shown in FIG. 16A. If the attachment of the pad to the lower substrate was done inappropriately, the pad can be removed and reworked in this way.

In the case of including a stretchable substrate, the pad may be easily removed by stretchably pulling the substrate layer 1520 as shown in FIG. 16B. Since the substrate layer 1520 and a pad layer 1530 are pulled out together, the pad is easily separated, and the reworkability is improved. Although the hard substrate such as the PET material also can be pulled out, there is a problem that peeling off the pad layer or adhesive layer is not easy and residual adhesive remains. When the pad includes the stretchable substrate, there may be almost no residual adhesive remains upon separation, and the pad layer may be neatly separated together with the stretchable substrate.

The stretchable substrate may be configured to have a predetermined thickness or more in order not to be broken when being stretched. For example, the thickness of the stretchable substrate may be 50 micrometers or more and 150 micrometers or less, but is not limited thereto.

Application of Resin

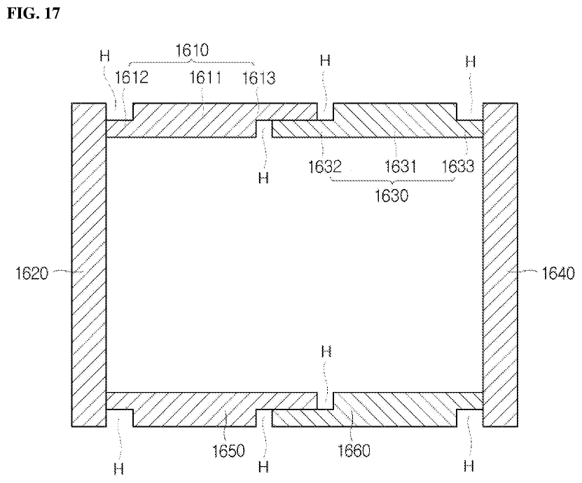

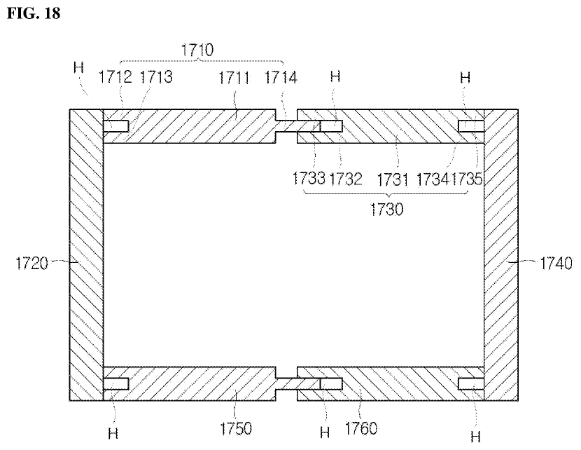

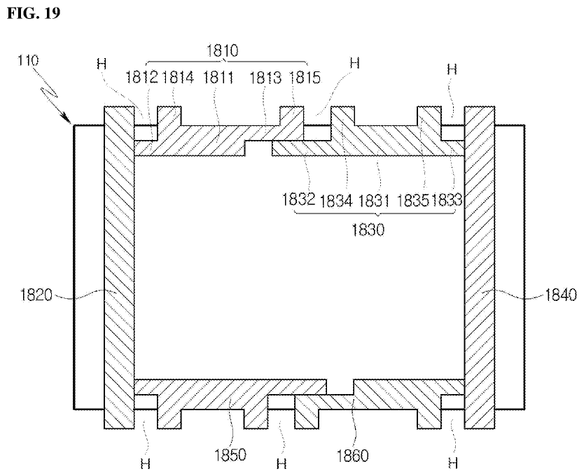

Referring to FIGS. 17 to 19, there is described an application of a resin. FIGS. 17 and 18 illustrate the pad to which a resin is applied before compressing of the cover glass of the present disclosure, and FIG. 19 illustrates the pad to which a resin is applied after compressing of the cover glass of the present disclosure. The lower substrate is not illustrated in FIGS. 17 and 18.

First, referring to FIG. 17, there is described the pad to which a resin is applied before compressing the cover glass. In FIG. 17, the pad may include a first partial pad 1610, a second partial pad 1620, a third partial pad 1630, a fourth partial pad 1640, a fifth partial pad 1650, and a sixth partial pad 1660. Further, the pad may include a groove H. In an embodiment, the partial pads may be disposed as to form the groove H. Here, the groove H may refer to an empty space in a plan view, which is formed by a contact of the partial pads. FIG. 17 illustrates the grooves (H) formed at the respective portions where the first partial pad 1610 and the second partial pad 1620 are in contact, where the first partial pad 1610 and the third partial pad 1630 are in contact, where the third partial pad 1630 and the fourth partial pad 1640 are in contact, etc. While the partial pads do not appear to overlap in the plan view, the partial pads are overlapping from a side view of the display device. In more detail, one groove H may be formed by at least three sides surrounded by the two partial pads in contact with each other. For example, as shown in FIG. 17, one groove H may have the three sides surrounded by a first center portion 1611 and a first protruding portion 1612 of the first partial pad 1610 and the second partial pad 1620. Here, the groove may be formed on the first protruding portion 1612 in a plan view. Also, one groove H may have the three sides surrounded a second protruding portion 1613 of the first partial pad 1610, and a third protruding portion 1632 and a second center portion 1631 of the third partial pad 1630. The second protruding portion 1613 and the third protruding portion 1632 may be in contact with each other vertically. Here, the groove may be formed on the third protruding portion 1632 in a plan view. The second protruding portion 1613 and the third protruding portion 1632 may be configured to be opposite to be upside down, to FIG. 17. In this case, the groove may be formed on the second protruding portion 1613 in a plan view. Further, a resin may be applied to the groove H in order to more effectively prevent the penetration of dust and moisture.

The display device according to an embodiment may further include a resin applied to the groove. For example, the resin may include a known optically-clear resin (OCR) material. The resin may be applied to various positions such as a side of the pad or between the partial pads. In one embodiment, after a groove to which the resin is applied is prepared in the display device, then the resin may be applied to the groove. When the resin is applied thereto, a gap that may occur during the process of combining the combining-type pads may be effectively sealed. The application of the resin, may be performed either before compressing of the portions where overlapping is performed or after compressing of the portions where overlapping is performed.

In FIG. 17, the groove H has a shape opening toward the outside. Here, the term “the outside” may refer to the outside of an edge portion of the display device. A pad may be disposed on the lower substrate 110, and then the resin may be applied to the groove H before the cover glass is disposed on the pad. The cover glass may be compressed thereafter. Since the groove is formed to open toward the outside, there is an advantage in which the application of the resin can be applied supplementally/additionally even after the compressing of the cover glass.

Referring to FIG. 18, there is described another embodiment of the pad for applying the resin before compressing of the cover glass. Referring to FIG. 18, the pads may include a first partial pad 1710, a second partial pad 1720, a third partial pad 1730, a fourth partial pad 1740, a fifth partial pad 1750, and a sixth partial pad 1760. Further, the pad may include a groove H. As shown in FIG. 18, the groove H may be a space with its all four sides closed. The groove H may be formed by a plurality of the partial pads surrounding its four sides. For example, one groove H may be formed by two first protruding portions 1712, 1713 and a first center portion 1711 of the first partial pad 1710, and the second partial pad 1720, surrounding the four sides of the groove. Alternatively, as shown in the upper middle portion of FIG. 18, two third protruding portions 1732 and 1733 of the third partial pad 1730 may surround the top and bottom sides of a second protruding portion 1714 of the first partial pad 1710, thereby one closed groove H is formed. That is, a groove H may be formed by the four sides surrounded by a plurality of the partial pads.

When the partial pad forms a closed groove H and the resin is applied to the groove H, the resin is not exposed to the outside, which improves the appearance in an aesthetical view. In other words, since the resin is applied to the enclosed space, the resin does not flow over to the outside. The partial pad may serve to prevent or at least reduce the resin from flowing over to the outside. When the cover glass is compressed thereafter, the resin is not exposed to the outside, which enhances the appearance in an aesthetical view.

Referring to FIG. 19, there is described a pad to which a resin is applied after compressing the cover glass. In FIG. 19, the pads may include a first partial pad 1810, a second partial pad 1820, a third partial pad 1830, a fourth partial pad 1840, a fifth partial pad 1850, and a sixth partial pad 1860. Further, the pad may include a groove H. As shown in FIG. 19, the pad may include a groove H opening toward the outside. A resin may be applied to the groove H. Even after compressing of the cover glass, since the groove H is open toward the outside, the resin can be applied to the groove from the outside. The partial pads may be configured or disposed to be combined as to have the groove H opening to the outside. For example, one groove H is formed on a portion where the first partial pad 1810 and the second partial pad 1820 are combined to each other, and one groove H is formed on a portion where the first partial pad 1810 and the third partial pad 1830 are combined.

According to an embodiment, the partial pad may have convex portions 1814, 1815, 1834, and 1835. The convex portions 1814, 1815, 1834, and 1835 are portions formed by extending of the partial pads to protrude beyond the periphery of the lower substrate 110. The convex portions 1814, 1815, 1834, and 1835 may respectively form a groove with the partial pad in contact therewith. For example, one groove H may be formed by the convex portion 1814 and a first protruding portion 1812 of the first partial pad, and the second partial pad 1820. Also, one groove H may be formed by the convex portion 1815 of the first partial pad 1810, and a third protruding portion 1832 and the convex portion 1834 of the third partial pad 1830.

In the embodiment of FIG. 19, since the resin is applied after compressing of the cover glass is performed, the resin application is made to the groove H opening to the outside from the outside of the display device. Since the convex portions 1814, 1815, 1834, and 1835 protrude to the outside of the lower substrate and the cover glass even after compressing of the cover glass is performed, the resin can be injected into the grooves between the protruding convex portions. The convex portions 1814, 1815, 1834, and 1835 have an effect of facilitating the resin application process. Filling the grooves H and the gap between the partial pads by the resin application, the waterproof and dustproof capabilities of the pad can be improved.

Embodiment of a Method for Manufacturing a Display Device

Hereinafter, referring to FIGS. 1 and 3, there is described a method for manufacturing the display device.

A method for manufacturing the display device 100 according to an embodiment may include a first step of disposing the first partial pad 122 on and along a periphery of the lower substrate 110 on which a display element is disposed, a second step of disposing the second partial pad 124 on and along the periphery of the lower substrate 110, wherein at least a portion of the first partial pad 122 and at least a portion of the second partial pad 124 are disposed as to overlap, a third step of disposing the cover glass 310 on the first partial pad 122 and the second partial pad 124 as to cover the lower substrate 110; and a fourth step of compressing the lower substrate 110 and the cover glass 310 as to fill the gap 410 between the first partial pad 122 and the second partial pad 124 and formed when overlappingly disposing the first partial pad 122 and the second partial pad 124.

In the second step of an embodiment, the pads may overlap as shown in the enlarged view of FIG. 1. Although the first partial pad 122 is disposed to be on the second partial pad 124 in FIG. 3, the second partial pad 124 may be disposed to be on the first partial pad 122.

In order not to form an excessive air gap in the fourth step of an embodiment, the display device may be compressed first at the center then towards the boundary gradually so that the contained air escapes. Alternatively, the display device may be compressed at a sufficiently low speed. This allows all unnecessary air to escape through the gap, and then the gap can be filled.

When the pad has the multilayer structure including the pad layer and the base layer, the second step may include a step of disposing the first partial pad 1430 and the second partial pad 1440 such that a first pad layer 1432 and the second pad layer 1442 are to be in contact with each other, as shown in FIG. 14. More specifically, the second step of FIG. 13 may include a step of, in an area where the first partial pad 1430 and the second partial pad 1440 overlap, disposing the first pad layer 1432 to be on the second pad layer 1442.

In FIG. 14, the first substrate layer 1434 is disposed to be in contact with the cover glass 1420 and the second substrate layer 1444 is disposed in contact with the lower substrate 1410, but on the other hand, the first partial pad and the second partial pad may be respectively turned by 180 degrees such that the first substrate layer is in contact with the lower substrate and the second substrate layer is in contact with the cover glass. Even in this case, the partial pad where the substrate layer is in contact with the cover glass to be an upper layer, and the partial pad where the substrate layer is in contact with the lower substrate to be a lower layer. With this arrangement, the pad layers of both partial pads can be in contact with each other.

It is to be understood by a person skilled in the art of the present disclosure that since the present disclosure can be practiced in other specific embodiments without departing from the technical ideas or essential features thereof, the embodiments described above are exemplary in all aspects and not to be taken in a limiting sense. The scope of the present disclosure is defined by the appended claims rather than by the description, and therefore all changes and modifications that fall within the metes and bounds of the claims, or equivalents of such metes and bounds are therefore intended to be embraced by the claims.

According to the present disclosure, the following embodiments are disclosed.

There is disclosed a display device including a lower substrate on which a display element is disposed, a pad disposed on and along a periphery of the lower substrate, and a cover glass disposed on the pad and covering the lower substrate, and the pad includes a first partial pad and a second partial pad, wherein at least a portion of the first partial pad and at least a portion of the second partial pad overlapping.

The first partial pad may be disposed on an upper portion of the lower substrate in plan view and have a first center portion and a first protruding portion having a width smaller than a width of the first center portion, and the second partial pad may be disposed on one side portion of the lower substrate in plan view and have a second center portion and a second protruding portion having a width smaller than a width of the second center portion, and the pad is configured such that at least a portion of the first protruding portion and at least a portion of the second protruding portion overlap.

The pad may be configured to have a concave area at one or more corners in plan view.

The first partial pad may be disposed to extend from the upper portion to an opposite side portion of the one side portion of the lower substrate, and the second partial pad may be disposed to extend from the one side portion to a lower portion of the lower substrate.

The first partial pad may be disposed on one side of the upper portion of the lower substrate in plan view and have a first center portion and a first protruding portion having a width smaller than a width of the first center portion, and the second partial pad may be disposed on the other side of the upper portion of the lower substrate in a plan view and to have a second center portion and a second protruding portion having a width smaller width of the second center portion, and the pad is configured such that at least a portion of the first protruding portion and at least a portion of the second protruding portion overlap.

The first protruding portion may comprise a body portion and a protrusion protruding upward or downward of the body portion in plan view, and the pad is configured such that the protrusion and at least a portion of the second protruding portion overlap.

The protrusion may protrude upward of the body portion, the second protruding portion may include a concave portion; and an overlapping portion formed under the concave portion in plan view, wherein the pad may be configured such that the protrusion and the overlapping portion overlap.

In an area where the first partial pad and the second partial pad overlap, the first partial pad may include a first substrate layer in contact with the lower substrate and a first pad layer disposed on the first substrate layer, and the second partial pad may include a second substrate layer in contact with the cover glass and a second pad layer disposed under the second substrate layer and on the first pad layer.

At least one of the first substrate layer and the second substrate layer may include a stretchable substrate.

A resin layer applied to the portion where overlapping is performed may be further included.

There is disclosed a method for manufacturing a display device including a first step of disposing a first partial pad on and along a periphery of a lower substrate on which a display element is disposed; a second step of disposing a second partial pad on and along the periphery of the lower substrate, wherein at least a portion of the first partial pad and at least a portion of the second partial pad are disposed as to overlap; a third step of disposing a cover glass on the first partial pad and the second partial pad as to cover the lower substrate; and a fourth step of compressing the lower substrate and the cover glass as to fill a gap which is between the first partial pad and the second partial pad and formed when disposing the first partial pad and the second partial pad to overlap.

It is included that the first partial pad may have a first center portion and a first protruding portion having a width smaller than a width of the first center portion, and the second partial pad may have a second center portion and a second protruding portion having a width smaller than a width of the second center portion, the first step may include a step of disposing the first partial pad on an upper portion of the lower substrate in plan view, and the second step may include a step of disposing the second partial pad at one side portion of the lower substrate in plan view, wherein at least a portion of the first protruding portion and at least a portion of the second protruding portion are disposed to overlap.

It is included that the first step may include a step of disposing the first partial pad to extend from the upper portion to an opposite side portion of the one side portion of the lower substrate, and the second step may include a step of disposing the second partial pad to extend from the one side portion to a lower portion of the lower substrate.

It is included that the first partial pad may have a first center portion and a first protruding portion having a width smaller than a width of the first center portion, and the second partial pad may have a second center portion and a second protruding portion having a width smaller than a width of the second center portion, the first step may include a step of disposing the first partial pad on one side of the upper portion of the lower substrate in plan view, and the second step may include a step of disposing the second partial pad on the other side of the upper portion of the lower substrate in plan view, wherein at least a portion of the first protruding portion and at least a portion of the second protruding portion are disposed to overlap.

It is included that the first protruding portion may comprise a body portion and a protrusion protruding upward or downward of the body portion in plan view, and the second step may include a step of disposing the protrusion and at least a portion of the second protruding portion to overlap.

It is included that the protrusion may protrude upward of the body portion, the second protruding portion may include a concave portion; and an overlapping portion formed under the concave portion in plan view, and the second step may include a step of disposing the protrusion and the overlapping portion to overlap.

It is included that the first partial pad may include a first substrate layer in contact with the lower substrate; and a first pad layer disposed on the first substrate layer, the second partial pad may include a second substrate layer in contact with the cover glass; and a second pad layer disposed under the second substrate layer, and the second step may include a step of, in an area where the first partial pad and the second partial pad overlap, disposing the second pad layer to be on the first pad layer.

At least one of the first substrate layer and the second substrate layer may include a stretchable substrate.

| | |
|---|---|
| 100, 1400: display device | 110, 1410: lower substrate |
| 120, 1300: pad | |
| 122, 810, 830, 875, 1010a, 1010b, 1110a, | |
| 1110b, 1430: first partial pad | |
| 124, 820, 840, 880, 1020a, 1020b, 1150a, | |
| 1150b, 1440: second partial pad | |
| 126, 850, 885: third partial pad | |
| 128, 860, 890: fourth partial pad | |
| 130: overlapping area | 140: concave area |
| 310, 1420: cover glass | 410: gap |
| 510: air gap | 600, 700: partial pad |
| 832, 834, 852, 854, 872, 874, 876, 878, | |
| 882, 884, 886, 888: sub-partial pad | |
| 610, 710: center portion | |
| 1120a, 1120b: first center portion | |
| 1160a, 1160b: second center portion | |
| 620, 720: protruding portion | |
| 836, 838, 873, H: groove | |
| 1012a, 1012b, 1120a, 1120b: first | |
| center portion | |
| 1014a, 1014b, 1130a, 1130b, 1210: first | |
| protruding portion | |
| 1022a, 1022b, 1160a, 1160b: second | |
| center portion | |
| 1024a, 1024b, 1170a, 1170b: second | |
| protruding portion | |
| 1132a, 1132b: first body portion | |
| 1172b: second body portion | |
| 1134a, 1134b: first protrusion | |
| 1174b: second protrusion | |
| 1240: protrusion | |
| 1220: concave portion | |
| 1230: overlapping portion | 1310, 1530: pad layer |
| 1320: substrate layer | 1330: adhesive layer |
| 1432: first pad layer | 1434: first substrate layer |
| 1436: first adhesive layer | 1442: second pad layer |
| 1444: second substrate layer | 1446: second adhesive layer |
| 1510: substrate layer including a PET | |
| substrate | |
| 1520: substrate layer including a | |
| stretchable substrate | |
| 1610, 1710, 1810: first partial pad | |
| 1611, 1711, 1811: first center portion | |
| 1612, 1712, 1713, 1812: first protruding | |
| portion | |
| 1613, 1714, 1813: second protruding portion | |
| 1620, 1720, 1820: second partial pad | |
| 1630, 1730, 1830: third partial pad | |
| 1631, 1731, 1831: second central portion | |
| 1632, 1732, 1733, 1832: third protruding | |
| portion | |
| 1633, 1734, 1735, 1833: fourth protruding | |
| portion | |
| 1640, 1740, 1840: fourth partial pad | |
| 1650, 1750, 1850: fifth partial pad | |
| 1660, 1760, 1860: sixth partial pad | |
| 1814, 1815, 1834, 1835: convex portion | |

What is claimed is:

1. A display device comprising:
a lower substrate;
a display element on the lower substrate, the display element configured to emit light;
a pad disposed on the lower substrate along a periphery of the lower substrate, the pad comprising a first partial pad and a second partial pad, wherein a portion of the first partial pad overlaps a portion of the second partial pad on the lower substrate; and
a cover glass on the pad, the cover glass covering the lower substrate and the pad.

2. The display device of claim 1, wherein the first partial pad is on an upper portion of the lower substrate in a plan view of the display device, the first partial pad including a first center portion and a first protruding portion that extends from the first center portion, wherein the first protruding portion has a width that is less than a width of the first center portion,
wherein the second partial pad is disposed on a first side portion of the lower substrate in the plan view, the second partial pad including a second center portion and a second protruding portion that extends from the second center portion, wherein the second protruding portion has a width that is less than a width of the second center portion, and
wherein at least a portion of the first protruding portion overlaps at least a portion of the second protruding portion.

3. The display device of claim 2, wherein the pad includes a concave area at one or more corners of the pad in the plan view.

4. The display device of claim 2, wherein the first partial pad extend from the upper portion of the lower substrate to a second side portion of the lower substrate that is opposite the first side portion of the lower substrate, and
wherein the second partial pad extends from the first side portion of the lower substrate to a lower portion of the lower substrate that is opposite the upper portion of the lower substrate.

5. The display device of claim 1, wherein the first partial pad is on a first side of an upper portion of the lower substrate in a plan view of the display device, the first partial pad including a first center portion and a first protruding portion that extends from the first center portion, wherein the first protruding portion has a width that is less than a width of the first center portion, and
wherein the second partial pad is disposed on a second side of the upper portion of the lower substrate that is opposite the first side in the plan view, the second partial pad including a second center portion and a second protruding portion that extends from the second center portion, wherein the second protruding portion has a width that is less than a width of the second center portion, and
wherein at least a portion of the first protruding portion overlaps at least a portion of the second protruding portion.

6. The display device of claim 5, wherein the first protruding portion comprises a body portion and a protrusion that protrudes in a first direction away from the body portion in the plan view or protrudes in a second direction away from the body portion that is opposite the first direction in the plan view, and
wherein the protrusion overlaps at least a portion of the second protruding portion.

7. The display device of claim 6, wherein the protrusion protrudes in the first direction,
wherein the second protruding portion comprises a concave portion that extends into the second protruding portion and an overlapping portion under the concave portion in the plan view,
wherein the protrusion of the first protruding portion overlaps the overlapping portion of the second protruding portion.

8. The display device of claim 1, wherein in an area where the first partial pad and the second partial pad overlap, the first partial pad comprises a first substrate layer that is in contact with the lower substrate and a first pad layer on the first substrate layer, and the second partial pad comprises a second substrate layer in contact with the cover glass and a second pad layer that is under the second substrate layer and on the first pad layer.

9. The display device of claim 8, wherein at least one of the first substrate layer and the second substrate layer comprises a stretchable substrate.

10. The display device of claim 1, further comprising:
a resin layer where the portion of first partial pad overlaps the portion of the second partial pad.

11. The display device of claim 1, wherein the first partial pad is disposed on an upper portion of the lower substrate, the first partial pad comprising a first center portion, a first protruding portion protruding from the first center portion to a first side, and a second protruding portion protruding to a second side;
wherein the second partial pad is disposed on a left side portion of the lower substrate, the second partial pad in contact with the first protruding portion; and
a groove formed on the first protruding portion in a plan view of the display device.

12. The display device of claim 11, wherein the pad further comprises:
a third partial pad comprising a second center portion and a third protruding portion that protrudes from the second center portion, the third protruding portion in contact with the second protruding portion.

13. The display device of claim 12, wherein the third protruding portion further comprises a groove in the plan view of the display device.

14. The display device of claim 13, wherein the third partial pad further comprises a fourth protruding portion that protrudes from the second center portion, and the pad further comprising:
a fourth partial pad disposed on a right side portion of the lower substrate and in contact with the fourth protruding portion, the fourth partial pad comprising a groove in the plan view.

15. A method for manufacturing a display device comprising:
disposing a first partial pad on a lower substrate along a periphery of the lower substrate on which a display element is disposed;
disposing a second partial pad on the lower substrate along the periphery of the lower substrate such that a portion of the first partial pad overlaps a portion of the second partial pad;
disposing a cover glass on the first partial pad and the second partial pad such that the cover glass covers the lower substrate, the first partial pad, and the second partial pad; and
compressing the lower substrate and the cover glass such that a gap that is between the first partial pad and the second partial pad is reduced.

16. The method for manufacturing a display device of claim 15, wherein the first partial pad includes a first center portion and a first protruding portion that extends from the first center portion, the first protruding portion having a width that is less than a width of the first center portion,
wherein the second partial pad includes a second center portion and a second protruding portion that extends from the second center portion, the second protruding portion having a width that is less than a width of the second center portion,
wherein the first partial pad is disposed on an upper portion of the lower substrate in a plan view of the display device, and the second partial pad is disposed at a first side portion of the lower substrate in the plan view,
wherein at least a portion of the first protruding portion overlaps at least a portion of the second protruding portion.

17. The method for manufacturing a display device of claim 16,
wherein the first partial pad is disposed to extend from the upper portion to a second side portion of the lower substrate that is opposite the first side portion, and
wherein the second partial pad is disposed to extend from the first side portion to a lower portion of the lower substrate that is opposite the upper portion of the lower substrate.

18. The method for manufacturing a display device of claim 15, wherein the first partial pad comprises a first center portion and a first protruding portion that extends from the first center portion, the first protruding portion having a width that is less than a width of the first center portion,
wherein the second partial pad comprises a second center portion and a second protruding portion that extends from the second center portion, the second protruding portion having a width that is less than a width of the second center portion,
wherein the first partial pad is disposed on a first side of an upper portion of the lower substrate in a plan view of the display device, and the second partial pad is disposed on a second side of the upper portion of the lower substrate that is opposite the first side in the plan view, wherein at least a portion of the first protruding portion overlaps at least a portion of the second protruding portion.

19. The method for manufacturing a display device of claim 18, wherein the first protruding portion comprises a body portion and a protrusion protruding that protrudes in a first direction away from the body portion in the plan view or protrudes in a second direction away from the body portion that is opposite the first direction in the plan view, and
wherein the protrusion and at least a portion of the second protruding portion are disposed to overlap.

20. The method for manufacturing a display device of claim 19, wherein the protrusion protrudes in the first direction,
wherein the second protruding portion comprises a concave portion that extends into the second protruding portion and an overlapping portion formed under the concave portion in the plan view, and
wherein the protrusion and the overlapping portion are disposed to overlap.

21. The method for manufacturing a display device of claim 15, wherein the first partial pad comprises a first substrate layer that is in contact with the lower substrate and a first pad layer disposed on the first substrate layer, and the second partial pad comprises a second substrate layer in contact with the cover glass and a second pad layer that is disposed under the second substrate layer,
wherein in an area where the first partial pad and the second partial pad overlap, the second pad layer is disposed on the first pad layer.

22. The method for manufacturing a display device of claim 21, wherein at least one of the first substrate layer and the second substrate layer comprises a stretchable substrate.

23. A display device comprising:
a lower substrate;
a display element on the lower substrate, the display element configured to emit light;
a pad disposed on the lower substrate along a periphery of the lower substrate, the pad comprising a first partial pad and a second partial pad, wherein a portion of the first partial pad overlaps a portion of the second partial pad on the lower substrate; and
a cover glass on the pad, the cover glass covering the lower substrate and the pad,
wherein an innermost outer edge of the first partial pad or an innermost outer edge of the second partial pad does not respectively extend past an outermost outer edge of the first partial pad or an outermost outer edge of the second partial pad in a plan view of the display device after compression of the lower substrate, the pad, and the cover glass.

24. The display device of claim 23, wherein the first partial pad comprises a first center portion and a first protruding portion that extends from the first center portion, wherein the first protruding portion has a width that is less than a width of the first center portion,
wherein the second partial pad comprises a second center portion and a second protruding portion that extends from the second center portion, wherein the second protruding portion has a width that is less than a width of the second center portion, and
wherein at least a portion of the first protruding portion overlaps at least a portion of the second protruding portion.

25. The display device of claim 24, wherein the pad comprises a concave portion formed due to the overlap of the portion of the first protruding portion and the portion of the second protruding portion.
